(19) United States
(12) Patent Application Publication
(10) Pub. No.: US 2026/0309643 A1
(43) Pub. Date: Oct. 8, 2026

(54) INTERFERENCE OBSERVATION DEVICE AND INTERFERENCE OBSERVATION METHOD

(71) Applicant: HAMAMATSU PHOTONICS K.K., Hamamatsu-shi, Shizuoka (JP)

(72) Inventors: Toyohiko YAMAUCHI, Shizuoka (JP); Natsuki SUZUKI, Shizuoka (JP)

(73) Assignee: HAMAMATSU PHOTONICS K.K., Hamamatsu-shi, Shizuoka (JP)

(21) Appl. No.: 19/483,341

(22) PCT Filed: Feb. 1, 2024
(86) PCT No.: PCT/JP2024/003346

§ 371 Date: Nov. 11, 2025

(30) Foreign Application Priority Data
Jun. 12, 2023 (JP) 2023-096088

(51) Int. Cl. G01N 21/95; G01N 21/45; G06N 20/00

(52) U.S. Cl. CPC G01N 21/9501; G01N 21/45; G06N 20/00; G01N 2201/0636

(57) ABSTRACT

Provided is an interference observation device comprising: a light source configured to output light; an interference optical system having a reference mirror and configured to split the light emitted from the light source into first light and second light and output interference light between the first light reflected by an observation object and the second light reflected by the reference mirror; an imaging element configured to detect the interference light; a processing unit configured to acquire an interference image on the basis of a detection result of the imaging element and acquire a degree of disorder of an image of a foreign substance region attached to the observation object in the interference image; and an output unit configured to output information about the degree of disorder acquired by the processing unit.

### TECHNICAL FIELD

An aspect of the present invention relates to an interference observation device and an interference observation method.

### BACKGROUND ART

An interference observation device including a light source configured to output light, an interference optical system configured to split the light output from the light source into first light and second light and output interference light between the first light reflected by an observation object and the second light reflected by a reference mirror, an imaging device configured to detect the interference light, and a processing unit configured to acquire an interference image on the basis of a detection result of the imaging device is known. As this type of technology, for example, Patent Literature 1 discloses a cell observation device that designed to distinguish types of cells by acquiring information such as optical thicknesses of cells.

### CITATION LIST

### Patent Literature

[Patent Literature 1] PCT International Publication No. WO2011/132587

[Patent Literature 2] Japanese Unexamined Patent Publication No. H08-124982

[Patent Literature 3] Japanese Unexamined Patent Publication No. H11-176898

### SUMMARY OF INVENTION

### Technical Problem

In the above-described interference observation device, a foreign substance may be attached to the observation object and, in this case, it is desirable to discriminate the foreign substance (i.e., distinguish the type of the foreign substance). In relation to this issue, for example, as described in Patent Literature 2, minute foreign substances attached to pattern surfaces and the like of semiconductor devices are a significant factor that reduces a yield rate of the semiconductor devices. Moreover, for example, as described in Patent Literature 2, to prevent the attachment of such foreign substances, it is important to quickly identify its source and take countermeasures to prevent contamination, and analysis of the composition and state of the foreign substances is essential for this purpose.

In relation to the composition of the foreign substances, for example, as described in Patent Literature 3, the presence of metallic contamination and organic contamination causes insulation breakdown when a gate oxide film is formed by thermal oxidation in a semiconductor manufacturing process. Moreover, for example, Patent Literature 3, the fact that organic contamination can cause deterioration of insulation even in the case of the attachment after the formation of a gate oxide film and a method for detecting and removing organic contamination are described.

Therefore, an aspect of the present invention is to provide an interference observation device and an interference observation method that enable a foreign substance attached to an observation object to be discriminated.

### Solution to Problem

As a result of the diligent study, the inventors have found that, in an interference image of an observation object to which a foreign substance is attached, a degree of disorder of an image in a foreign substance region varies with a type of foreign substance. Consequently, an aspect of the present invention is completed by obtaining the knowledge that the foreign substance can be discriminated if the degree of disorder of the image of the foreign substance region in the interference image can be obtained.

That is, an interference observation device according to an aspect of the invention is “[1] an interference observation device comprising: a light source configured to output light; an interference optical system having a reference mirror and configured to split the light emitted from the light source into first light and second light and output interference light between the first light reflected by an observation object and the second light reflected by the reference mirror; an imaging element configured to detect the interference light; a processing unit configured to acquire an interference image on the basis of a detection result of the imaging element and acquire a degree of disorder of an image of a foreign substance region attached to the observation object in the interference image; and an output unit configured to output information about the degree of disorder acquired by the processing unit.”

In this interference observation device, when a foreign substance is attached to the observation object, it is possible to output the information about the degree of disorder of the image of the foreign substance region in the interference image. Consequently, it is possible to discriminate the foreign substance attached to the observation object according to the above-described knowledge on the basis of the information about the degree of disorder that has been output.

An interference observation device according to an aspect of the present invention may be [2] “the interference observation device according to [1], comprising a storage unit configured to store a foreign substance classification model related to a relationship between the degree of disorder of the foreign substance and a type of foreign substance, wherein the processing unit discriminates the type of foreign substance from the acquired degree of disorder with reference to the foreign substance classification model stored in the storage unit.” In this case, it is possible to discriminate the foreign substance attached to the observation object with reference to the foreign substance classification model.

An interference observation device according to an aspect of the present invention may be [3] “the interference observation device according to [2], comprising a learning unit configured to generate a foreign substance classification model related to the relationship between the degree of disorder of the foreign substance and the type of foreign substance by machine learning using interference images of a plurality of types in cases where the foreign substance is attached to the observation object as training data.” In this case, machine learning can be used to generate a foreign substance classification model.

An interference observation device according to an aspect of the present invention may be [4] “the interference observation device according to [2] or [3], wherein the foreign substance includes reflective and transmissive foreign substances.” In this case, it is possible to discriminate whether the foreign substance attached to the observation object is a reflective foreign substance or a transmissive foreign substance.

An interference observation device according to an aspect of the present invention may be [5] “the interference observation device according to [4], wherein the reflective foreign substance includes a semiconductor, and wherein the transmissive foreign substance includes an organic material.” In this case, it is possible to discriminate whether the foreign substance attached to the observation object is a reflective semiconductor or a transmissive organic material.

An interference observation device according to an aspect of the present invention may be [6] “the interference observation device according to any one of [1] to [5], wherein the output unit includes a display unit configured to display information about the degree of disorder.” In this case, it is possible to easily ascertain the information about the degree of disorder of the image in the foreign substance region in the interference image.

An interference observation device according to an aspect of the present invention may be [7] “the interference observation device according to any one of [1] to [6], wherein the interference optical system is configured so that an optical path length of an optical path of the second light is changeable.” In this case, it is possible to highlight the foreign substance in the acquired interference image by changing the optical path length of the optical path of the second light. Thereby, it is possible to easily discriminate the foreign substance.

An interference observation method according to an aspect of the invention is [8] “an interference observation method comprising: a light output step of outputting light from a light source; an interference light output step of splitting the light emitted from the light source into first light and second light and outputting interference light between the first light reflected by an observation object and the second light reflected by a reference mirror; an interference light detection step of detecting the interference light with an imaging element; a processing step of acquiring an interference image on the basis of a detection result of the imaging element and acquiring a degree of disorder of an image of a foreign substance region attached to the observation object in the interference image; and an output step of outputting information about the degree of disorder acquired in the processing step.”

In this interference observation method, if a foreign substance is attached to the observation object, it is possible to output information about the degree of disorder of the image in the foreign substance region in the interference image. Therefore, it is possible to discriminate foreign substances attached to the observation object according to the above-mentioned knowledge on the basis of the information about the output degree of disorder.

### Advantageous Effects of Invention

According to the aspect of the present invention, it is possible to provide an interference observation device and an interference observation method that enable a foreign substance attached to an observation object to be discriminated.

### BRIEF DESCRIPTION OF DRAWINGS

FIG. 1 is a configuration diagram showing an interference observation device according to an embodiment.

FIG. 2 is an enlarged view of an observation object shown in FIG. 1.

FIG. 3 is a flowchart showing an example of a method for calculating a degree of disorder.

FIG. 4 is an explanatory diagram of a relationship between a phase image and a degree of disorder.

FIG. 5(a) is a diagram showing the phase image. FIG. 5(b) is a diagram showing a real part of a complex image corresponding to the phase image of FIG. 5(a). FIG. 5(c) is a diagram showing an imaginary part of the complex image corresponding to the phase image of FIG. 5(a).

FIG. 6(a) is a diagram showing a real part of a first smoothed complex image. FIG. 6(b) is a diagram showing an imaginary part of the first smoothed complex image.

FIG. 7(a) is a diagram showing a real part of a second smoothed complex image. FIG. 7(b) is a diagram showing an imaginary part of the second smoothed complex image.

FIG. 8(a) is a diagram showing a real part of a third smoothed complex image. FIG. 8(b) is a diagram showing an imaginary part of the third smoothed complex image.

FIG. 9(a) is a diagram showing a first phase difference image. FIG. 9(b) is a diagram showing a second phase difference image. FIG. 9(c) is a diagram showing a third phase difference image.

FIG. 10(a) is a diagram showing an enlarged portion of a phase image including a reflective foreign substance. FIG. 10(b) is a diagram showing an enlarged portion of a phase difference image corresponding to the phase image of FIG. 10(a).

FIG. 11(a) is a diagram showing an enlarged portion of a phase image including a transmissive foreign substance. FIG. 11(b) is a diagram showing an enlarged portion of a phase difference image corresponding to the phase image of FIG. 11(a).

FIG. 12 is a diagram showing an image of a local phase variation in the second phase difference image.

FIG. 13 is an explanatory diagram of a foreign substance classification model.

FIG. 14 is a diagram showing a reflective foreign substance degree table.

FIG. 15 is a flowchart showing an example of a method for training the foreign substance classification model.

FIG. 16 is a flowchart showing an example of an interference observation method using an interference observation device.

FIG. 17 is an explanatory diagram of a foreign substance classification model according to a modification example.

### DESCRIPTION OF EMBODIMENTS

Hereinafter, embodiments will be described in detail with reference to the drawings. In the following description, the same reference signs are used for the same or corresponding elements, and redundant descriptions will be omitted.

### Interference Observation Device

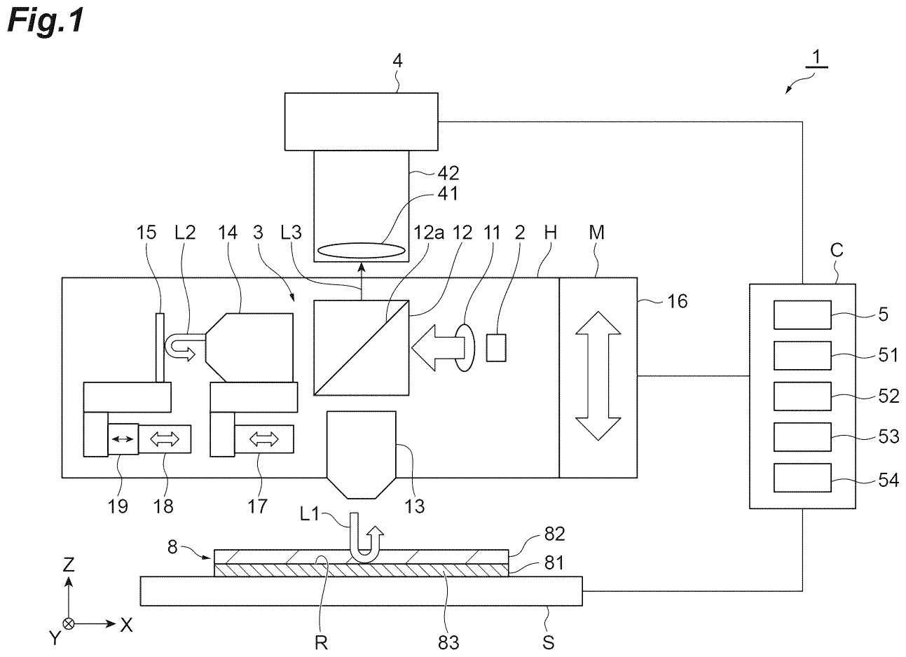

As shown in FIG. 1, an interference observation device 1 includes a light source 2, an interference optical system 3, an imaging element 4, a processing unit 5, and a stage S. The interference observation device 1 is an interference microscope for observing an observation object 8 arranged on the stage S using light interference. Although the observation object 8 is, for example, a semiconductor device, it may also be other industrial samples formed of metal, glass, resin, liquid crystal, polymer compounds, or the like. The observation object 8 may be a biological sample such as a cell. Hereinafter, an X direction, a Y direction perpendicular to the X direction, and a Z direction perpendicular to both the X direction and the Y direction are set as shown in FIG. 1 and descriptions will be given using the set directions.

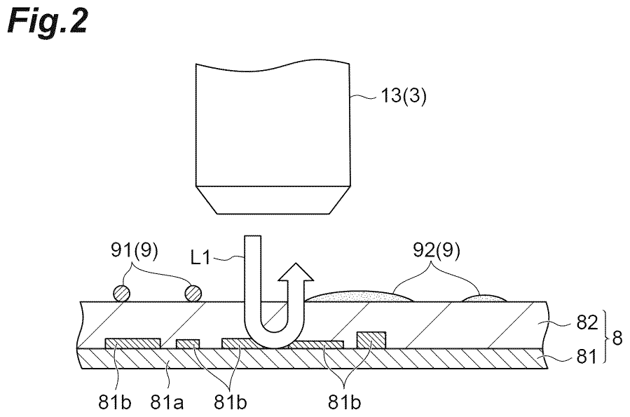

The interference observation device 1 is configured so that the interior of the observation object 8 can be observed. In the internal observation, an observation surface R arranged within the observation object 8 is observed. In this example, the observation object 8 is a so-called wafer with a film. As shown in FIGS. 1 and 2, the observation object 8 includes a device unit 81 constituting a patterned chip, and a film part 82, which is a passivation film on the surface of the device unit 81. The device unit 81 includes a pattern of functional elements 81b formed on a wafer 81a. The observation surface R is the surface of the device unit 81.

The light source 2 outputs incoherent light. The light source 2 is, for example, a lamp-based light source such as a halogen lamp, a light emitting diode (LED) light source, a super luminescent diode (SLD) light source, an amplified spontaneous emission (ASE) light source, or the like. The interference optical system 3 is configured as a Linnik interference type in this example. The interference optical system 3 has a lens 11, a beam splitter 12, an objective lens 13, a reference objective lens 14, and a reference mirror 15. The interference optical system 3 is arranged within a housing H together with the light source 2 and constitutes an optical module M. The optical module M can be moved in the Z direction by a predetermined actuator 16. The Z direction is parallel to an optical axis of the objective lens 13 and parallel to a direction in which first light L1 to be described below is incident on the observation object 8.

The lens 11 collimates light output from the light source 2. The beam splitter 12 is, for example, a prism with an optical plane 12a and splits the light collimated by the lens 11 into the first light L1 and second light L2 at an optical plane 12a. The beam splitter 12 outputs the first light L1 to the objective lens 13 and outputs the second light L2 to the reference objective lens 14. Moreover, the first light L1 reflected by the observation surface R of the observation object 8 is incident on the optical plane 12a via the objective lens 13, and the second light L2 reflected by the reference mirror 15 is incident via the reference objective lens 14. The first light L1 and the second light L2 are combined at the optical plane 12a to form interference light L3. The interference optical system 3 outputs the interference light L3 to the imaging element 4.

The objective lens 13 condenses the first light L1 output from the beam splitter 12 onto the observation object 8 arranged on the stage S. Moreover, the first light L1 reflected by the observation surface R of the observation object 8 is incident on the objective lens 13. The objective lens 13 outputs the first light L1 that is incident to the beam splitter 12. The reference objective lens 14 guides the second light L2 output from the beam splitter 12 to the reference mirror 15 and condenses the light onto the reference mirror 15. Moreover, the reference objective lens 14 outputs the second light L2 reflected by the reference mirror 15 to the beam splitter 12. The reference mirror 15 reflects the second light L2 output from the reference objective lens 14 so that the second light L2 returns to the reference objective lens 14.

A stepping motor 17 for moving the reference objective lens 14 and a stepping motor 18 and a piezoelectric element 19 for moving the reference mirror 15 are further arranged within the housing H of the optical module M. The stepping motor 17 moves the reference objective lens 14 in the optical axis direction (e.g., the X direction) of the second light L2 perpendicular to the Z direction. The stepping motor 18 and the piezoelectric element 19 move the reference mirror 15 in the optical axis direction of the second light L2. To obtain interference fringes with a high SN ratio, it is preferable to adjust the optical path length from the beam splitter 12 to the reference mirror 15 so that the optical path length approximately matches an optical path length from the beam splitter 12 to the observation surface (reflection surface) R.

Response times of the stepping motors 17 and 18 are greater than 10 msec, and a response time of the piezoelectric element 19 is less than 1 msec. In other words, the response time of the piezoelectric element 19 is shorter than those of the stepping motors 17 and 18. The stroke (minimum movement distance) of the stepping motors 17 and 18 is a few mm, and the stroke of the piezoelectric element 19 is approximately 10 um. In other words, the stroke of the piezoelectric element 19 is smaller than those of the stepping motors 17 and 18. Lifetime drive counts of the stepping motors 17 and 18 are less than 1 million, and a lifetime drive count of the piezoelectric element 19 is more than 10 billion. In other words, the lifetime drive count of the piezoelectric element 19 is greater than those of the stepping motors 17 and 18.

Examples of the imaging element 4 include image sensors (cameras) such as a CCD area image sensor and a CMOS area image sensor. The imaging element 4 detects (images) the interference light L3 output from the interference optical system 3 (the beam splitter 12). A lens 41 and a lens barrel 42 are arranged between the imaging element 4 and the interference optical system 3. The lens 41 forms an image of the interference light L3 output from interference optical system 3 on an imaging plane of the imaging element 4. The lens 41 is housed within the lens barrel 42. The lens barrel 42, for example, is formed in a cylindrical shape, and is fixed to the imaging element 4 to surround the imaging plane.

The processing unit 5 is communicatively connected to each part of the interference observation device 1, including the light source 2, the interference optical system 3, the imaging element 4, and the stage S, and acquires interference images on the basis of a result of detecting the interference light L3 in the imaging element 4. Interference images include, for example, phase images, amplitude images, complex images, various images to be described below, and images equivalent to any of these.

The processing unit 5, for example, includes a computer C including a processor (CPU), a RAM, and a ROM which are storage media. The computer C has a storage region (a storage unit) 51 configured to store various types of information, an input unit 52 configured to receive inputs of various types of information, a display unit 53 configured to display various types of information, and a learning unit 54 configured to generate a foreign substance classification model (to be described below) by machine learning. The input unit 52 is, for example, a device that receives operation inputs from the user, and is, for example, a mouse, a keyboard, or the like. The display unit 53 is, for example, a display configured to display an image. The input unit 52 and the display unit 53, for example, may commonly include a touch panel. In this case, the input unit 52 and the display unit 53 may include a graphical user interface (GUI). Although the processing unit 5, the storage region 51, the input unit 52, the display unit 53, and the learning unit 54 are configured as a single device in this example, at least one thereof may be configured as a separate device and may be configured as, for example, a portable terminal or the like.

The stage S is a stage for arranging the observation object 8 and is movable along an XY plane perpendicular to the Z direction in which the first light L1 is incident on the observation object 8. Thereby, in the interference observation device 1, it is possible to observe (acquire interference images of) the observation surface R of the observation object 8 while moving the stage S along the XY plane, i.e., while changing an observation position of the observation object 8.

In the interference observation device 1, incoherent light is first output from the light source 2 (a light output step). The light is collimated by the lens 11 and split into first light L1 and second light L2 by the beam splitter 12. The first light L1 is condensed onto the observation object 8 by the objective lens 13, reflected on a boundary of the observation object 8, and input to the beam splitter 12 through the objective lens 13. The second light L2 is condensed by the reference objective lens 14 onto the reference mirror 15, reflected by the reference mirror 15, and input to the beam splitter 12 through the reference objective lens 14. The beam splitter 12 combines the first light L1 and the second light L2 that have been input and outputs the interference light L3 (an interference light output step). The interference light L3 that has been output is detected by the imaging element 4 (an interference light detection step). An interference image is acquired by the processing unit 5 on the basis of a detection result of the imaging element 4 (a processing step).

Moreover, in the interference observation device 1, the imaging element 4 performs an imaging process for acquiring four interference images, and the processing unit 5 constructs (acquires) one phase image on the basis of the four acquired interference images. The piezoelectric element 19 moves the reference mirror 15 finely in accordance with a timing at which the four interference images are captured. Thereby, an optical path length difference between the first light L1 and the second light L2 is made different among the four interference images. An amount of movement of the reference mirror 15 to acquire the four interference images is smaller than a wavelength λ of the light output from the light source 2. In this example, an optical path length difference (a phase shift interval) of the second light L2 among the four interference images is λ/4. When the reference mirror 15 is moved finely so that the change width in the optical path length is λ/4, if it is noted that the reference light (the second light L2) reciprocates along the reference optical path (the optical path length of the second light L2), an actual movement amount step of the reference mirror 15 is λ/8, and this value is 66.5 nm in the case of 2=532 nm. A method of acquiring interference images is not limited to the method in the above-described example, and may be any of various known methods.

In present embodiment, the processing unit 5 calculates and acquires the degree of disorder in the region of the foreign substance 9 attached to the observation object 8 in the interference image, and discriminates the foreign substance 9 from the acquired degree of disorder. The foreign substance 9 serving as a discrimination target includes at least a reflective foreign substance 91 that is reflective to the first light L1 and a transmissive foreign substance 92 that is transmissive to the first light L1. The reflective foreign substance 91 includes, for example, silicon scrap (silicon pieces), which are semiconductors. The transmissive foreign substance 92 is particularly an organic material, and includes, for example, thirsty stains of ethanol. The foreign substance 9 serving as a discrimination object is not limited in its type and may be various types of elements.

Non-Patent Literature 1: P. Burt and E. Adelson, “The Laplacian Pyramid as a Compact Image Code,” in IEEE Transactions on Communications, vol. 31, no. 4, pp. 532-540, April 1983

The above Non-Patent Literature 1 discloses a method of extracting a feature quantity of an image by creating a plurality of smoothed images using different smoothing filter sizes for an original image and utilizing a difference image between the images with the different smoothing filter sizes. However, because the phase is wrapped from-n to n in phase images, there are challenges in applying smoothing filters directly to the phase. An example of a technique for performing smoothing filtering and generating a difference image in the presence of phase wrapping will be described below.

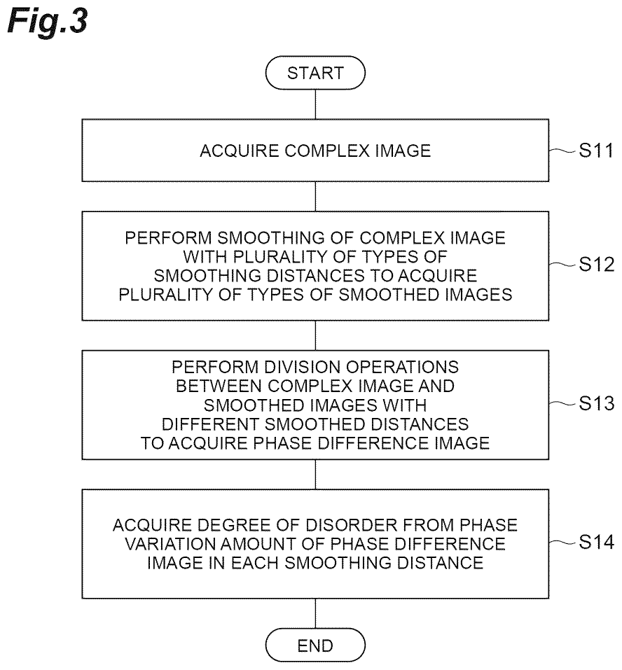

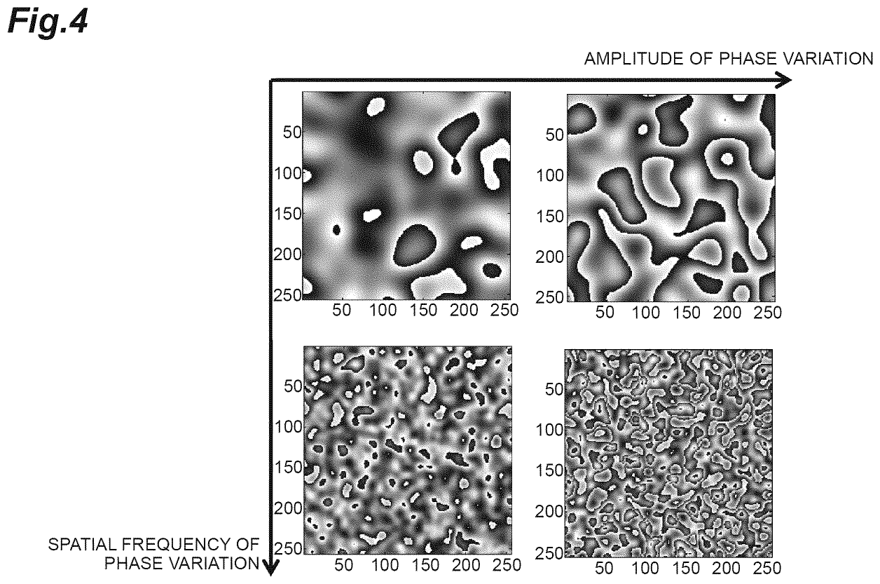

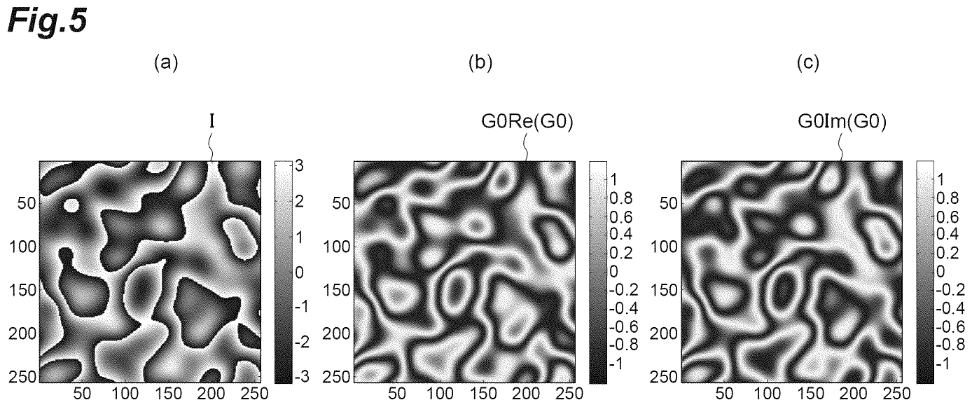

An example of a method in which the processing unit 5 calculates the degree of disorder in the interference image will be described in detail below with reference to the flowchart of FIG. 3. Because the phase images are wrapped from -π to π, as shown in FIG. 4, it is difficult to compare the acquired phase images with each other in evaluating the phase variation. For example, the four phase images in FIG. 4 all contain phases from -π to π to the same degree, making their comparison difficult when the degree of disorder in the interference image is evaluated. Moreover, when local phase variation is evaluated, an evaluation value is significantly changed between a region straddling phase wrapping and a region not straddling. Therefore, instead of directly calculating the standard deviation of the phase image I (see FIG. 5(a)), the processing unit 5 calculates and acquires a complex image G0 (see FIG. 5(b) and 5(c)) corresponding to a phase image I (step S11). The complex image G0 is an image represented by a two-dimensional array of complex numbers where the real part is an image G0Re (see FIG. 5(b)) and the imaginary part is an image G0Im (see FIG. 5(c)), and an argument of the complex image G0 corresponds to the phase image I.

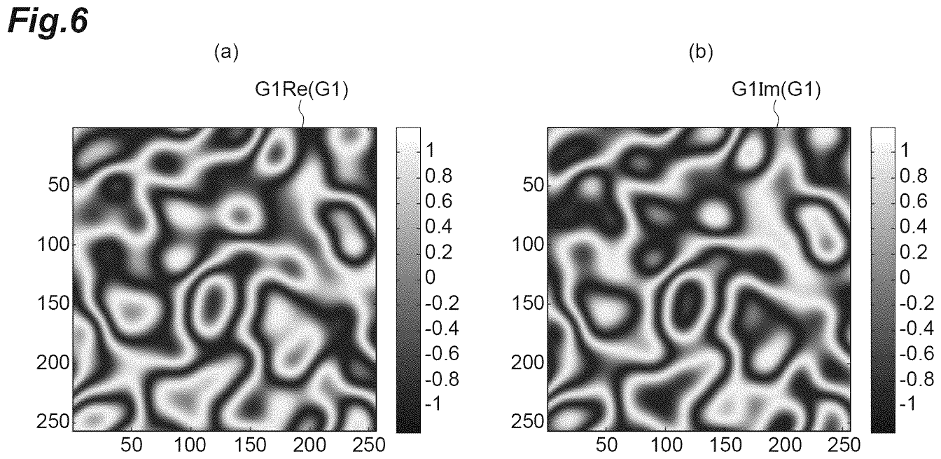

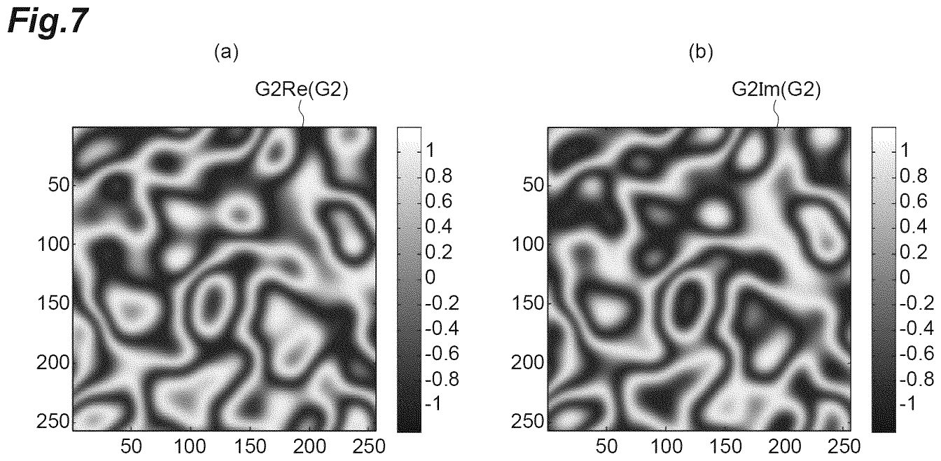

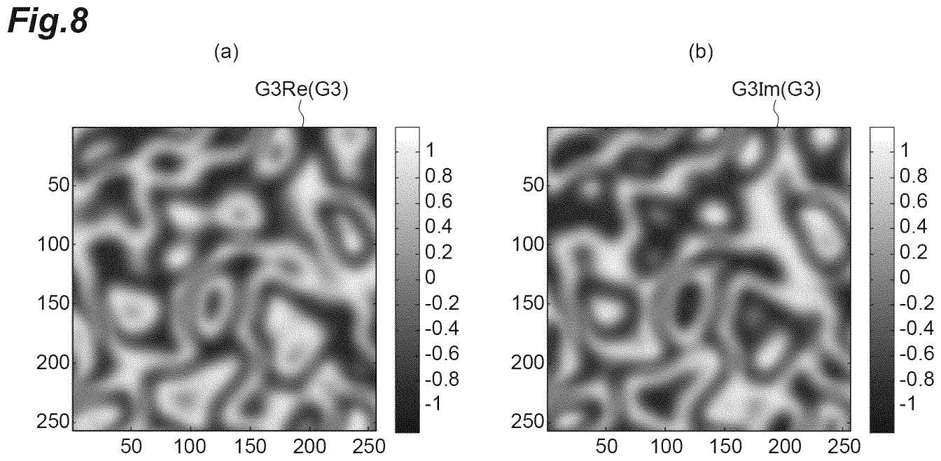

Subsequently, the processing unit 5 performs smoothing of the complex image G0 with a plurality of types of smoothing distances (i.e., smoothing window sizes) to acquire a plurality of types of smoothed complex images (step S12). Specifically, as shown in FIG. 6(a) and 6(b), the processing unit 5 performs smoothing (a convolution operation) on the complex image G0 with a window size of 2×2 to obtain a first smoothed complex image G1. As shown in FIG. 7(a) and 7(b), the processing unit 5 smooths the complex image G0 with a window size of 4×4 to obtain a second smoothed complex image G2. As shown in FIG. 8(a) and 8(b), the processing unit 5 smooths the complex image GO with a window size of 8 ×8 to obtain a third smoothed complex image G3.

In addition, in smoothing a complex image, it is assumed that a smoothing filtering process is applied to each of the real and imaginary parts of the image. The first to third smoothed complex images G1 to G3 are defined as follows, as in the case of the complex image G0. The first smoothed complex image G1 is an image represented by a two-dimensional array of complex numbers with the real part as an image G1Re (see FIG. 6(a)) and the imaginary part as an image G1Im (see FIG. 6(b)). The second smoothed complex image G2 is an image represented by a two-dimensional array of complex numbers with the real part as an image G2Re (see FIG. 7(a)) and the imaginary part as an image G2Im (see FIG. 7(b)). The third smoothed complex image G3 is an image represented by a two-dimensional array of complex numbers with the real part as an image G3Re (see FIG. 8(a)) and the imaginary part as an image G3Im (see FIG. 8(b)).

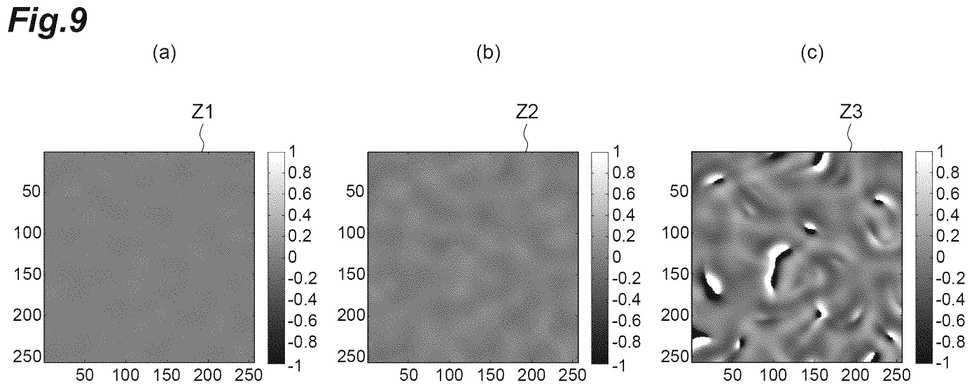

Subsequently, the processing unit 5 acquires a plurality of phase difference images for indexing how much the phase varies with a specific spatial frequency by calculating an argument after performing division operations between the complex image G0, the first smoothed complex image G1, the second smoothed complex image G2, and the third smoothed complex image G3 (step S13). Specifically, processing unit 5 calculates a phase difference of the first smoothed complex image G1 for the complex image G0 by dividing the complex image G0 by the first smoothed complex image G1 and acquiring the argument (i.e., Arg(complex image G0/first smoothed complex image G1)). Here, Arg(C) is a function that computes the argument for a complex number C. Thereby, a first phase difference image Z1 (see FIG. 9(a)) indicating the phase variation (ΔL=2) between pixels that are a smoothing distance 2 away from each other is acquired.

The processing unit 5 calculates the phase difference of the second smoothed complex image G2 for the first smoothed complex image G1 by dividing the first smoothed complex image G1 by the second smoothed complex image G2 to acquire the argument (i.e., Arg(first smoothed complex image G1/second smoothed complex image G2)). Thereby, a second phase difference image Z2 (see FIG. 9(b)) indicating the phase variation (ΔL=4) between pixels that are a smoothing distance of 4 away from each other is acquired. Furthermore, the processing unit 5 calculates the phase difference of the third smoothed complex image G3 for the second smoothed complex image G2 by dividing the second smoothed complex image G2 by the third smoothed complex image G3 to acquire the argument (i.e., Arg(second smoothed complex image G2/third smoothed complex image G3)). Thereby, a third phase difference image Z3 (see FIG. 9(c)) indicating the phase variation (ΔL=8) between pixels that are a smoothing distance of 8 away from each other is acquired. In addition, it should be noted that in general, a phase difference between a complex number C1 of an argument Φ1 and a complex number C2 of an argument Φ2 is expressed as Arg(b l /C2).

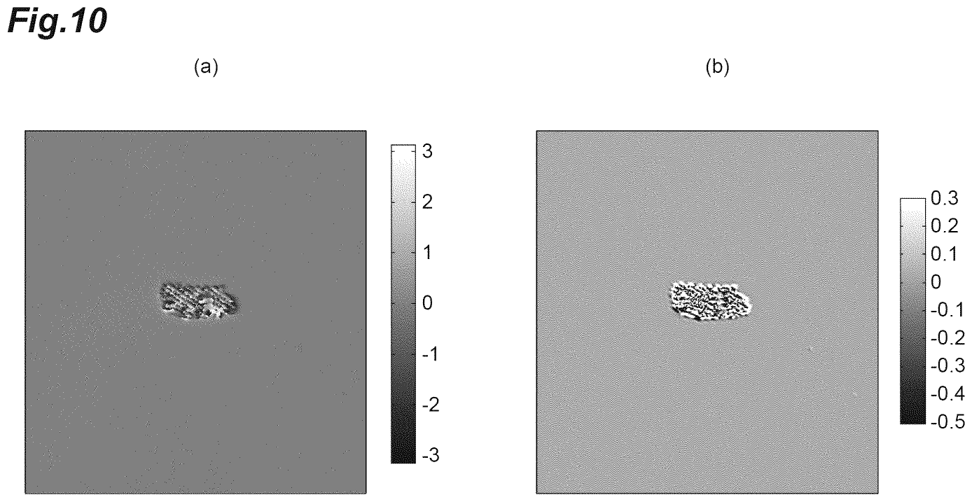

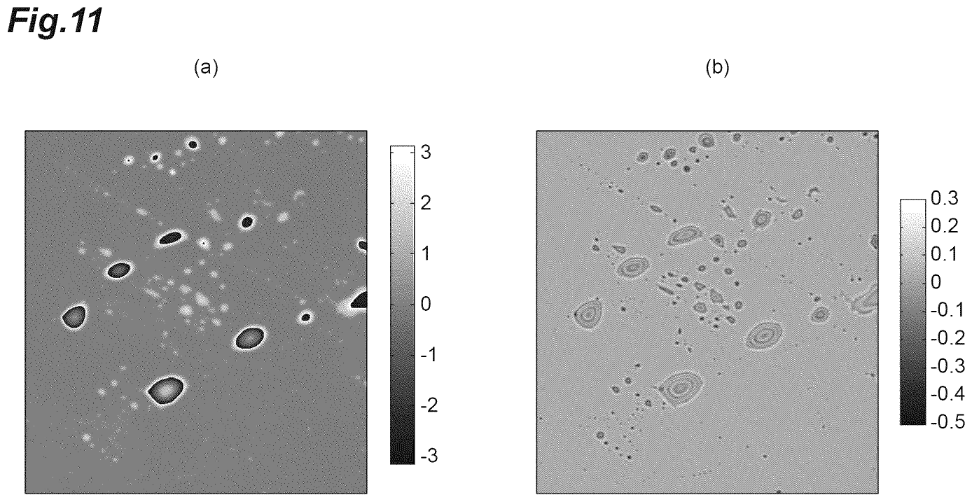

FIG. 10(a) is a diagram showing an enlarged portion of a phase image including a reflective foreign substance 91. FIG. 10(b) is a diagram showing an enlarged portion of a phase difference image corresponding to the phase image of FIG. 10(a). In FIG. 10(b), the phase difference image is for ΔL=4. The processing unit 5 can acquire the phase difference image shown of FIG. 10(b) on the basis of the phase image of FIG. 10(a). FIG. 11(a) is a diagram showing an enlarged portion of a phase image including a transmissive foreign substance 92. FIG. 11(b) is a diagram showing an enlarged portion of a phase difference image corresponding to the phase image of FIG. 11(a). In FIG. 11(b), the phase difference image is for ΔL=4. The processing unit 5 can obtain the phase difference image shown in FIG. 11(b) on the basis of the phase image of FIG. 11(a).

The processing unit 5 calculates a first phase variation amount, which is its feature quantity, at each pixel (at each coordinate position) of the first phase difference image Z1. The first phase variation amount is a standard deviation of the first phase difference image Z1. In each pixel of the second phase difference image Z2, the processing unit 5 calculates the second phase variation amount, which is its feature quantity. The second phase variation is the standard deviation of the second phase difference image Z2. In each pixel of the third phase difference image Z3, the processing unit 5 calculates a third phase variation amount, which is its feature quantity. The third phase variation amount is a standard deviation of the third phase difference image Z3.

The processing unit 5 acquires the degree of disorder for each pixel on the basis of the first to third phase variation amounts for each pixel (step S14). The degree of disorder is a feature quantity vector obtained by aligning the first to third phase variation amounts. The degree of disorder is a multidimensional parameter, and is a three-dimensional parameter here. The degree of disorder is acquired for each pixel of the image. According to this degree of disorder, which is obtained by comparing phase difference images using several different smoothing filters, it is possible to classify phase structures with different frequencies.

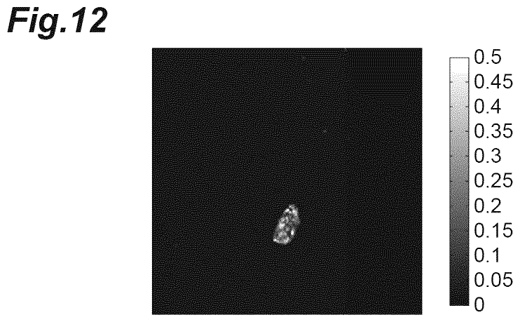

The processing unit 5 extracts the foreign substance 9 in the interference image. Specifically, the processing unit 5 extracts the foreign substance 9 using a local variation amount in the phase difference image as an index. The example shown in FIG. 12 is an image of the local phase variation in the second phase difference image Z2 with ΔL=4. The processing unit 5 isolates a region of pixels having a local phase variation exceeding a threshold value in the second phase difference image Z2 as a region where the foreign substance 9 is located. In addition, a process for extracting the foreign substance 9 is not limited, and various known methods, for example, including a method using separately captured bright visual field images and the like can be used.

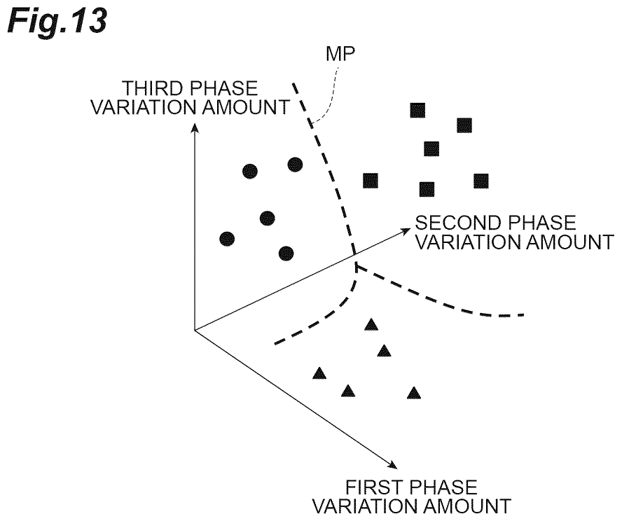

The processing unit 5 discriminates the type of foreign substance 9 from the acquired degree of disorder with reference to the foreign substance classification model stored in the storage region 51. The foreign substance classification model is a standard classification reference for classifying the foreign substances 9. The foreign substance classification model corresponds to a classification function of quantifying a “degree of reflective foreign substance” or a “degree of transmissive foreign substance” by assigning the degree of disorder. The degree of reflective foreign substance is an index that can be linked to an individual foreign substance 9, and is a value indicating a degree of reflectivity of the foreign substance 9 related to the first light L1. The degree of transmissive foreign substance is an index that can be linked to an individual foreign substance 9 and is a value indicating a degree of transmissivity of the foreign substance 9 related to the first light L1. The foreign substance classification model is obtained by defining a classification plane (a boundary plane) that can classify a plurality of types of foreign substances 9 in a multidimensional space. For example, the foreign substance classification model shown in FIG. 13 is a model for classifying three types of foreign substances and is obtained by defining a classification plane MP in a three-dimensional space with the first to third phase variation amounts as an axis.

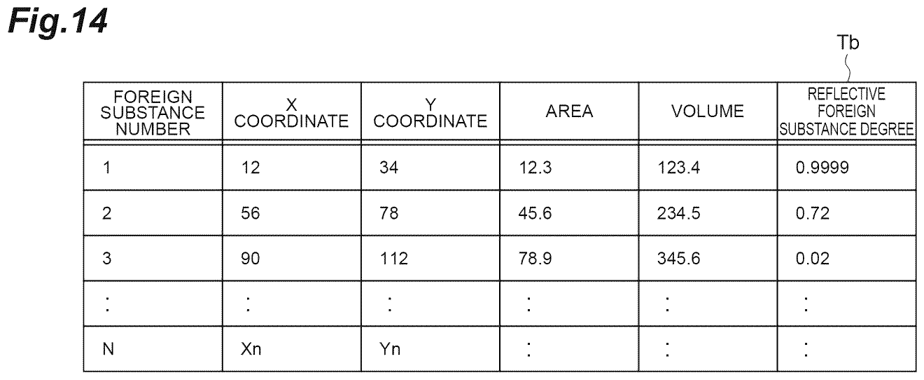

The display unit 53 displays information about the degree of disorder calculated by the processing unit 5. The display unit 53 displays information about the type of foreign substance 9 determined by processing unit 5. The display unit 53 constitutes the output unit that outputs information about the degree of disorder acquired by processing unit 5. For example, the display unit 53 displays a reflective foreign substance degree table Tb (see FIG. 14) related to the reflective foreign substance degree of each foreign substance 9 as information about the degree of disorder.

The reflective foreign substance degree table Tb is generated by the processing unit 5. The reflective foreign substance degree table Tb is a table showing the positions of the plurality of foreign substances 9 in the interference image and the reflective foreign substance degree of each of the plurality of foreign substances 9. An “area” in the reflective foreign substance degree table Tb is an area corresponding to each foreign substance 9 in the interference image. A “volume” of the reflective foreign substance degree table Tb is a value obtained by integrating luminance values of the pixels included in the area corresponding to each foreign substance 9 in the interference image across the entire area. For example, a “volume” of an area with 2×2 pixels and a phase value of 3 [radians] is 2×2×3=12 [radian pixels\hat{ }2]. The unit may be converted into [radians·μm\hat{ }2] or may be converted into [μm\hat{ }3] using a proportional relationship between the thickness of the foreign substance and the phase value. In the example of the reflective foreign substance degree table Tb shown in FIG. 14, it is possible to determine that a type of foreign substance 9 with a reflective foreign substance degree of 0.9999 is a reflective foreign substance 91 and it is possible to discriminate that a type of foreign substance 9 with a reflective foreign substance degree of 0.02 is a transmissive foreign substance 92.

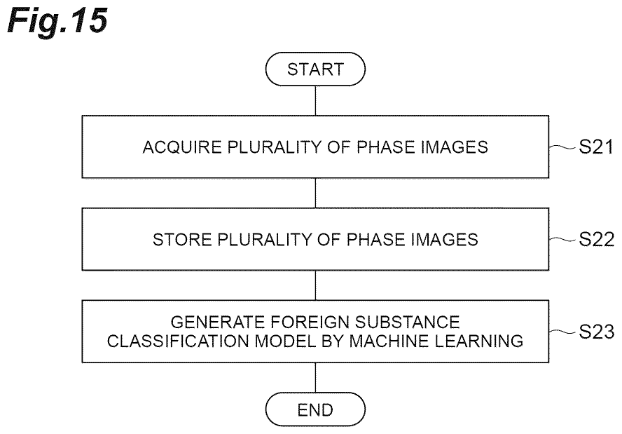

The learning unit 54 generates a foreign substance classification model by machine learning using a plurality of types of interference images as training data when foreign substances 9 are attached to the observation object 8. The learning unit 54 stores the generated foreign substance classification model in the storage region 51. An example of a foreign substance classification model training method is described in detail below using the flowchart of FIG. 15.

First, phase images of a plurality of types of observation objects 8 to which the foreign substance 9 is attached are acquired as training data (step S21). The above-described step S21 can be implemented by performing the step of detecting the interference light L3 with the imaging element 4 to acquire a phase image with respect to a plurality of types of observation objects 8 to which the foreign substance 9 is attached. For example, the phase images as the training data include information about the type of each foreign substance 9 included in the phase image as annotation information. The phase images as training data are limited to quantitative phase images and mathematically equivalent images. For example, an image that stores the real and imaginary parts of a phase image as complex data is mathematically equivalent to a quantitative phase image because the corresponding quantitative phase image can be created by inverse tangent calculation. The phase image serving as training data may be as follows or may be a combination of the following images.
(a) Interference image measured in advance by a manufacturer of the interference observation device 1 (hereinafter referred to simply as a “manufacturer”) and stored in a computer on a network
(b) Interference image measured in advance by a user of the interference observation device 1 (hereinafter referred to simply as a “user”) and stored in a user-managed computer.
(c) Interference image measured by the user during the generation of the foreign substance classification model

Subsequently, a plurality of types of phase images acquired in the above-described step S21 are stored in the storage region 51 (the above-described step S22). The learning unit 54 generates the foreign substance classification model by machine learning using the plurality of types of phase images that have been stored as training data (step S23). A type and/or configuration of an algorithm used to generate the foreign substance classification model is not particularly limited. Types of algorithms include, for example, random forest decision trees, multilayer perceptrons (neural networks), and the like. The configuration of the algorithm includes the number of intermediate layers, the number of units in each layer, the number of branches, objective variables, explanatory variables, and the like. The algorithm type and/or configuration may be generated by support vector machines or deep learning. The type and/or configuration of the algorithm may be generated by logistic regression analysis if the foreign substance classification model is a model that classifies two types of foreign substances.

The above-described step S22 may be performed by the operation of the manufacturer. In this case, a plurality of acquired interference images may be stored online or in an image database attached to the device. The above-described step S22 may be performed by an operation of the user. In this case, the plurality of acquired interference images may be stored in a file. The above-described step S23 may be performed by the operation of the manufacturer or user.

### Example of Operation

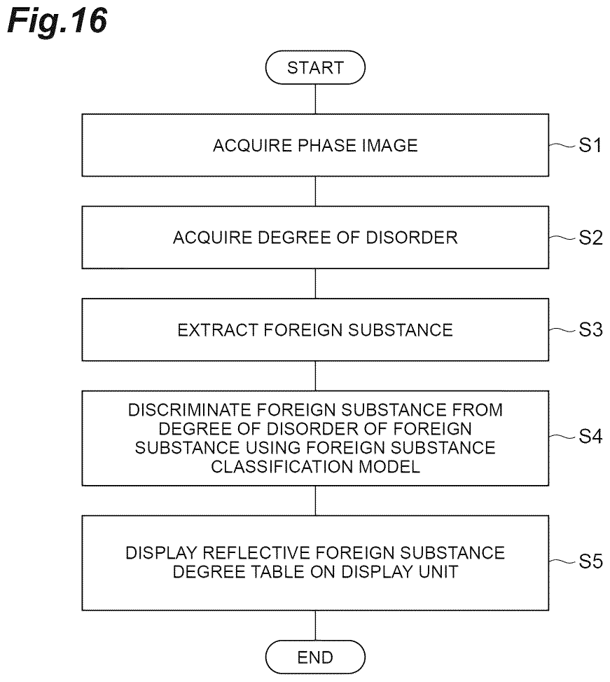

Next, an interference observation method using the interference observation device 1 will be described with reference to FIG. 16. In the following example, an example in which the observation surface R inside the interior of the observation object 8 is observed and the foreign substance 9 is attached to a surface (outer surface) of the film part 82 of the observation object 8 will be described.

First, the imaging element 4 acquires a captured image of the observation object 8 (step S1). In the above-described step S1, a position of the objective lens 13 is adjusted so that the focus of the objective lens 13 is aligned with the observation surface R of the observation object 8, and an interference image is acquired by the imaging element 4. Specifically, the optical image formation by the objective lens 13 and the lens 41 is adjusted so that the observation surface R and the light-receiving surface of the imaging element 4 are optically conjugate. The processing unit 5 performs the above-described steps S11 to S14 to acquire the degree of disorder of each pixel in the interference image (step S2).

Subsequently, the processing unit 5 extracts the foreign substance 9 in the interference image (step S3). In the above-described step S3, using an amount of local variation in the phase difference image obtained from the interference image as an index, a pixel (a coordinate position) where each foreign substance 9 is present in the interference image is extracted. Subsequently, the processing unit 5 acquires the degree of disorder in the region of the foreign substance 9 in the interference image. The processing unit 5 acquires the degree of disorder in the image of each foreign substance region on the basis of the degree of disorder in each pixel of the interference image acquired in the above-described step S2 and the pixel of each foreign substance 9 extracted in the above-described step S3. Also, the processing unit 5 discriminates the foreign substance from the degree of disorder of the image in each foreign substance region using the foreign substance classification model stored in the storage region 51 (step S4: processing step). The display unit 53 displays the reflective foreign substance degree table Tb as an output of information about the degree of disorder in the interference image in the region of each foreign substance 9 (step S5: output step). In the above-described step S5, the display unit 53 may further display information about the type of each foreign substance 9.

### Operation and Effects

In the interference image of the observation object 8 to which the foreign substance 9 is attached, it is found that the degree of disorder in the region of the foreign substance 9 varies with the type of the foreign substance 9. For example, in the reflective foreign substance 91, the image becomes a diffraction pattern of scattering because the foreign substance 9 scatters the first light L1 and the reflected light from the foreign substance 9 and the reflected light from the observation surface (reflection surface) R overlap each other, but it is found that such a pattern is unlikely to occur in the transmissive foreign substance 92. Consequently, it is found that if the degree of disorder in the region of the foreign substance 9 in the interference image can be obtained, it is possible to accurately discriminate the foreign substance 9 that is not easily discriminated by an aspect ratio or optical volume alone. In this regard, in the interference observation device 1 and the interference observation method, information about the degree of disorder in the region of the foreign substance 9 in the interference image is output when the foreign substance 9 is attached to the observation object 8. Consequently, according to the interference observation device 1 and the interference observation method, it is possible to discriminate the foreign substance 9 attached to the observation object 8 by distinguishing its type, i.e., discriminate the foreign substance 9 on the basis of information about the degree of disorder in the interference image in the region of the foreign substance 9 in the output interference image.

The interference observation device 1 and the interference observation method have the storage region 51 that stores a foreign substance classification model, and the processing unit 5 discriminates the type of foreign substance from the acquired degree of disorder with reference to the foreign substance classification model stored in the storage region 51. In this case, the foreign substance 9 attached to the observation object 8 can be discriminated with reference to the foreign substance classification model in the storage region 51.

The interference observation device 1 and the interference observation method include the learning unit 54 configured to generate a foreign substance classification model by machine learning using a plurality of interference images of the foreign substance 9 attached to the observation object 8 as training data. In this case, the machine learning can be used to generate the foreign substance classification model.

In the interference observation device 1 and the interference observation method, the foreign substance 9 includes reflective and transmissive foreign substances. In this case, it is possible to discriminate whether the foreign substance 9 is a reflective or transmissive foreign substance. In the interference observation device 1 and the interference observation method, the reflective foreign substance 91 includes silicon, a semiconductor, and the transmissive foreign substance 92 includes an organic material. In this case, it is possible to discriminate whether the foreign substance 9 attached to the observation object 8 is silicon with reflective properties or an organic material with transmissive properties.

The interference observation device 1 and the interference observation method include the display unit 53 configured to display information about the degree of disorder. In this case, information about the degree of disorder in the region of the foreign substance 9 in the interference image can be easily ascertained.

In the interference observation device 1 and the interference observation method, by employing a phase difference image based on a smoothed image of a complex image in the above-described steps S11 to S14 of acquiring the degree of disorder, the amount of local phase variation in the interference image including a wrapping of 2π or more in phase can be quantified. Because the image processing in the above-described steps S11 to S14 does not use phase unwrapping, it is not affected by various errors caused by the phase unwrapping. Moreover, the same calculation can be used to extract a region with a large local variation in phase, regardless of whether the image includes a wrapping of 2π or more in phase.

In the interference observation device 1 and the interference observation method, the amount of phase variation (standard deviation) of the phase difference image is used as an example of a multidimensional parameter of the degree of disorder. Because the amount of phase variation in the phase difference image can be evaluated in many ways by changing a size of the smoothing filter, it can be easily made multidimensional. Another example of a multidimensional parameter of the degree of disorder may be a contrast difference relative to the surrounding reflection intensity of the interference fringe amplitude in the region of the foreign substance 9.

In addition, the interference optical system 3 of the present embodiment is configured so that the optical path length of the optical path of the second light L2 (reference optical path length) can be changed. In this case, as shown in the next example, by changing the optical path length of the optical path of the second light L2, it is possible to highlight the foreign substance 9 attached to a surface other than the observation surface R of the observation object 8 in the acquired interference image and therefore it is possible to easily discriminate the foreign substance 9. In other words, the processing unit 5 controls the piezoelectric element 19 so that the reference mirror 15 is moved to a front position (a first position), and the first phase image is acquired by the imaging element 4. The reference mirror 15 is moved to a rear position (a second position) by controlling the piezoelectric element 19 with the processing unit 5, and the second phase image is acquired by the imaging element 4. The processing unit 5 extracts only bright spots of the threshold value or larger by performing threshold value processing, which is a known method, on an average image between a first phase image K1 and a second phase image K2 to acquire a bright spot extraction phase image, which is an interference image in which the foreign substance 9 is highlighted. By acquiring the degree of disorder in the region of the foreign substance 9 in this bright spot extraction phase image, the foreign substance 9 can be easily discriminated. In addition, in this case, the stepping motor 18 may be used as the moving mechanism of the reference mirror 15 instead of the piezoelectric element 19. The focal condition of the optical path of the second light L2 may be changed by moving the reference objective lens 14. Instead of using the average image between the first phase image K1 and the second phase image K2 for bright spot extraction, either the first phase image K1 or the second phase image K2 may be used.

### Modified Examples

As described above, an aspect of the present invention is not limited to the above-described embodiments.

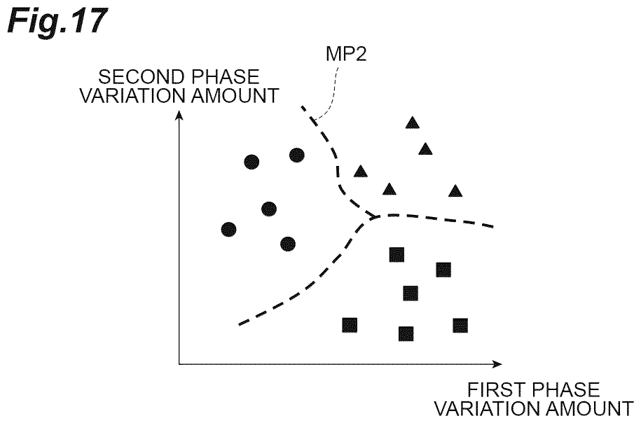

Although the degree of disorder is a three-dimensional parameter in the above-described embodiment, the present invention is not limited thereto and the degree of disorder may be a multidimensional parameter of four or more dimensions. For example, the dimension of the degree of disorder may be made arbitrarily high by setting four or more types of smoothing window sizes when a plurality of types of smoothed complex images are acquired. Moreover, for example, the number of dimensions can be reduced by a method of principal component analysis or the like, and the degree of disorder can be used as a one-or two-dimensional parameter. As an example, the degree of disorder may be a two-dimensional parameter obtained by aligning the first and second phase variation amounts. In this case, the foreign substance classification model may be, for example, as shown in FIG. 17, a model that classifies three types of foreign substances and may be obtained by defining a classification curve MP2 in a two-dimensional space with the first and second phase variation amounts as axes.

Although the foreign substance classification model generated by the learning unit 54 by machine learning is stored in the storage region 51 in the above-described embodiment, the present invention is not limited thereto. A foreign substance classification model generated in advance by the manufacturer or user may be stored in the storage region 51 without the learning unit 54. In this case, the hardware used to generate the foreign substance classification model may be the user's personal computer or a cloud server. Thereby, it is possible to reduce the amount of data to be read and speed up an operation during initial setup.

The reflective foreign substance degree table Tb related to the reflective foreign substance degree of each foreign substance 9 is displayed on the display unit 53 in the above-described embodiment. However, instead of or in addition to this, information about the transmissive foreign substance degree may be displayed on the display unit 53, or other information about the degree of disorder may be displayed on the display unit 53. In the above-described embodiment, after the reflective or transmissive foreign substance degree is quantified, it may be determined whether it is greater or less than the threshold value, and the foreign substance 9 may be discriminated by a determination result.

The above-described embodiment has the display unit 53 as an output unit, but the output unit is not limited to the display unit 53 and it is only necessary to output information about the degree of disorder acquired by the processing unit 5. For example, the output unit may be a transmission unit that transmits information about the degree of disorder. For example, the output unit may be a part that outputs information about the degree of disorder to elements outside or inside the interference observation device 1. In the above-described embodiment, the information about the degree of disorder may be stored in the storage region 51 or a separate storage medium, or transmitted externally, instead of or in addition to being displayed on the display unit 53.

Although the foreign substance classification model is acquired by reading it from the storage region 51 in the above-described embodiment, the foreign substance classification model may be acquired by downloading it from an external source such as a cloud server or by reading it from a recipe database attached to the device. In the above-described embodiment, various physical objects may be used as the observation object 8. For example, the observation object may be a so-called capped device, a so-called bonded wafer, or a single wafer.

Although the extraction of foreign substance 9 (the above-described step S3) is performed after the acquisition of the degree of disorder (the above-described step S2) in the above-described embodiment, the degree of disorder may be acquired after the extraction of the foreign substance 9. In this case, for example, a region where the foreign substance 9 is present in the interference image is extracted by threshold value processing or the like and the degree of disorder in the extracted interference image of the foreign substance 9 is calculated. Incidentally, when the foreign substance 9 is extracted after the degree of disorder of the interference image is acquired, a processing speed can be increased because simple processing can be performed on the interference image.

A focal condition of the optical path of the second light L2 is changed by moving the reference mirror 15 in the above-described embodiment. However, instead of or in addition to this, the focal condition of the optical path of the second light L2 may be changed by moving the reference objective lens 14. In this case, the processing unit 5 may construct a first interference image on the basis of the plurality of interference images acquired by the imaging element 4 in a state in which the reference objective lens 14 is moved to the front position by controlling the stepping motor 17. The processing unit 5 may construct a second interference image on the basis of the plurality of interference images acquired by the imaging element 4 in a state in which the reference objective lens 14 is moved to the rear position by controlling the stepping motor 17. Also, the processing unit 5 may separate observation surface information from non-observation surface information on the basis of the first and second interference images.

In the above-described embodiment, the relative position between the objective lens 13 and the observation object 8 is adjusted by moving the objective lens 13 in the Z direction by the actuator 16. However, in place of or in addition to this, the stage S may be moved in the Z direction to adjust the relative position. In this case, the stage S is configured to be movable in the Z direction in addition to the XY direction. In this case, the actuator 16 may be omitted. It is only necessary for the stage S to be movable in a direction that intersects a direction in which the first light L1 is incident on the observation object 8. For example, the stage S may be movable in a direction inclined to the XY plane. The actuators that drive the reference objective lens 14 and reference mirror 15 are not limited to the stepping motors 17 and 18, but can be other actuators such as servomotors.

Although the interference optical system 3 is configured as a Linnik interference type in the above-described embodiment, the interference optical system 3 may be configured as a Michelson or Mirau interference type. The reference objective lens 14 may be omitted. In the above-described embodiment, the number of interference images used to construct the phase image is not particularly limited and may be one or more.

Various materials and shapes can be applied to each configuration in the above-described embodiment and the above-described modification examples without being limited to the above-described materials and shapes. Moreover, the configurations in the embodiment or the modification examples described above can be arbitrarily applied to the configuration in another embodiment or modification examples.

### REFERENCE SIGNS LIST

1 Interference observation device, 2 Light source, 3 Interference optical system, 4 Image sensor, 5 Processing unit, 8 Observation object, 9 Foreign substance, 14 Reference objective lens, 15 Reference mirror, 51 Storage region (storage unit), 53 Display unit (output unit), 91 Reflective foreign substance, 92 Transmissive foreign substance, L1 First light, L2 Second light, L3 Interference light, R Observation surface, Tb Reflective foreign substance degree table (information about degree of disorder)

1. An interference observation device comprising:
a light source configured to output light;
an interference optical system having a reference mirror and configured to split the light emitted from the light source into first light and second light and output interference light between the first light reflected by an observation object and the second light reflected by the reference mirror;
an imaging element configured to detect the interference light;
a processing unit configured to acquire an interference image on the basis of a detection result of the imaging element and acquire a degree of disorder of an image of a foreign substance region attached to the observation object in the interference image; and
an output unit configured to output information about the degree of disorder acquired by the processing unit.

2. The interference observation device according to claim 1, comprising a storage unit configured to store a foreign substance classification model related to a relationship between the degree of disorder of the foreign substance and a type of foreign substance,
wherein the processing unit discriminates the type of foreign substance from the acquired degree of disorder with reference to the foreign substance classification model stored in the storage unit.

3. The interference observation device according to claim 2, comprising a learning unit configured to generate a foreign substance classification model related to the relationship between the degree of disorder of the foreign substance and the type of foreign substance by machine learning using interference images of a plurality of types in cases where the foreign substance is attached to the observation object as training data.

4. The interference observation device according to claim wherein the foreign substance includes reflective and transmissive foreign substances.

5. The interference observation device according to claim 4,
wherein the reflective foreign substance includes a semiconductor, and
wherein the transmissive foreign substance includes an organic material.

6. The interference observation device according to claim 1, wherein the output unit includes a display unit configured to display information about the degree of disorder.

7. The interference observation device according to claim 1, wherein the interference optical system is configured so that an optical path length of an optical path of the second light is changeable.

8. An interference observation method comprising:
a light output step of outputting light from a light source;
an interference light output step of splitting the light emitted from the light source into first light and second light and outputting interference light between the first light reflected by an observation object and the second light reflected by a reference mirror;
an interference light detection step of detecting the interference light with an imaging element;
a processing step of acquiring an interference image on the basis of a detection result of the imaging element and acquiring a degree of disorder of an image of a foreign substance region attached to the observation object in the interference image; and
an output step of outputting information about the degree of disorder acquired in the processing step.
